(19) United States
(12) Patent Application Publication
(10) Pub. No.: US 2026/0324046 A1
(43) Pub. Date: Oct. 15, 2026

(54) SEMICONDUCTOR STRUCTURE WITH EXTENDED CHANNEL WIDTH AND METHOD FOR MANUFACTURING THE SAME

(71) Applicant: TAIWAN SEMICONDUCTOR MANUFACTURING COMPANY, LTD., Hsinchu (TW)

(72) Inventors: Yi-Ruei JHAN, Hsinchu (TW); Wei Ting WANG, Hsinchu (TW); Kuan-Ting PAN, Hsinchu (TW); Shi Ning JU, Hsinchu (TW); Kuo-Cheng CHIANG, Hsinchu (TW); Chih-Hao WANG, Hsinchu (TW)

(73) Assignee: TAIWAN SEMICONDUCTOR MANUFACTURING COMPANY, LTD., Hsinchu (TW)

(21) Appl. No.: 19/179,888

(22) Filed: Apr. 15, 2025

(51) Int. Cl. H10D 84/01; H10D 84/83

(52) U.S. Cl. CPC H10D 84/0151; H10D 84/0128; H10D 84/832

(57) ABSTRACT

A method for manufacturing a semiconductor structure includes: a semiconductor structure includes: a first fin structure and a second fin structure disposed on a substrate, the first fin structure including a first base region and a first extended channel region disposed on the first base region, the second fin structure including a second base region and a second extended channel region disposed on the second base region, the first extended channel region having a first end surface facing a second end surface of the second extended channel region; and an isolation structure disposed on the substrate and between the first and second base regions. The first end surface has a first distance to an imaginary plane which is equidistant from the first and second end surfaces. The first sidewall has a second distance to the imaginary plane. The first distance is less than the second distance.

### BACKGROUND

At present, integrated circuits (ICs) are widely used in consumer electronics products (such as mobile phones), high performance computing applications, and automotive electronics products. Scaling down the size of semiconductor devices leads to decrease in chip size, which is in accordance to Moore's Law. However, decrease in the chip size incurs problems, such as increased resistance and parasitic effects, causing limitation in device performance. In order to allow the electronics products to have high device performance, various approaches are being continuously developed for optimizing the transistors in the ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing a semiconductor structure in accordance with some embodiments.

FIGS. 2 to 16B illustrate schematic views of intermediate stages of the method depicted in FIG. 1 in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “top,” “bottom,” “upper,” “lower,” “over,” “beneath,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, or other numerical values used in the specification and claims, are to be understood as being modified in all instances by the term “about” even if the term “about” is not explicitly recited with the values, amounts or ranges. Accordingly, unless indicated to the contrary, the numerical parameters set forth in the following specification and appended claims are not and need not be exact, but may be approximations and/or larger or smaller than specified as desired, may encompass tolerances, conversion factors, rounding off, measurement error, and other factors known to those of skill in the art depending on the desired properties sought to be obtained by the presently disclosed subject matter. For example, the term “about,” when used with a value, can capture variations of, in some aspects ±20%, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions and could be understood by those skilled in the art after reviewing the present disclosure.

The term “source/drain portion(s)” may refer to a source or a drain, individually or collectively dependent upon the context.

The present disclosure is directed to a semiconductor structure having extended channels, and a method for manufacturing the same. Each of the channels, which is extended using the method of the present disclosure, has a width that is greater than a width of a base region protruding from a substrate. Therefore, the current in each of the extended channels may be greater than the current in a channel that is not extended, thereby improving the device performance of MOSFETs in the semiconductor structure.

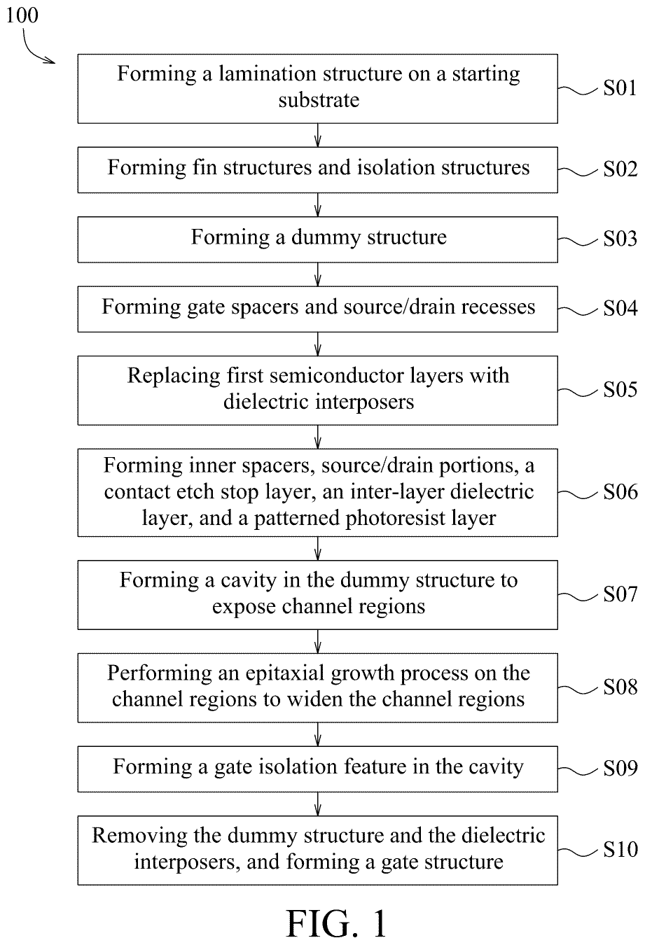

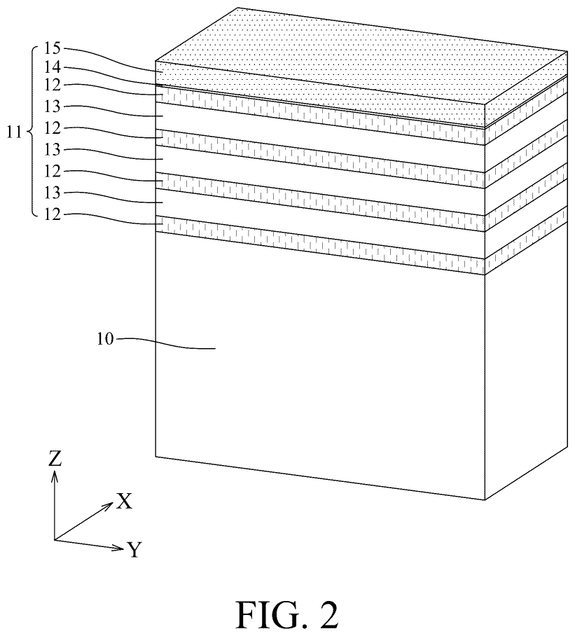

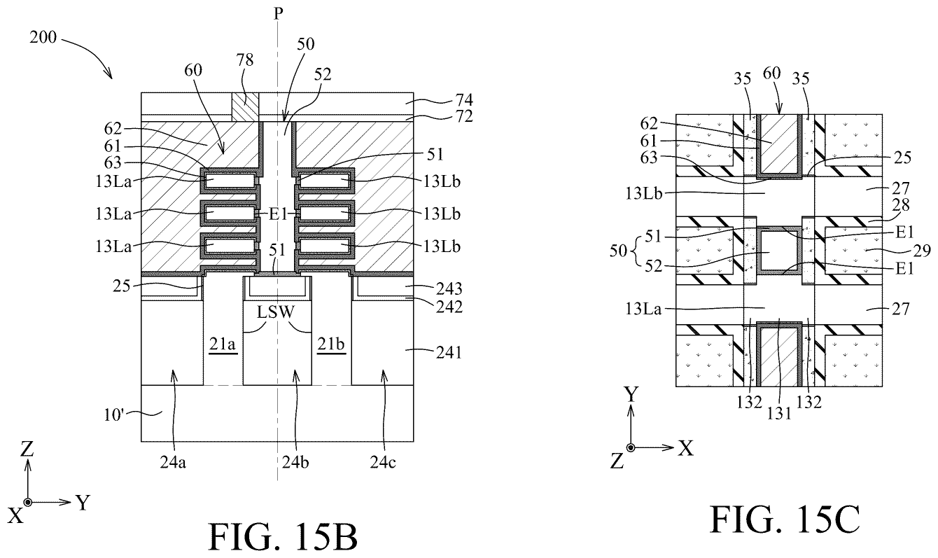

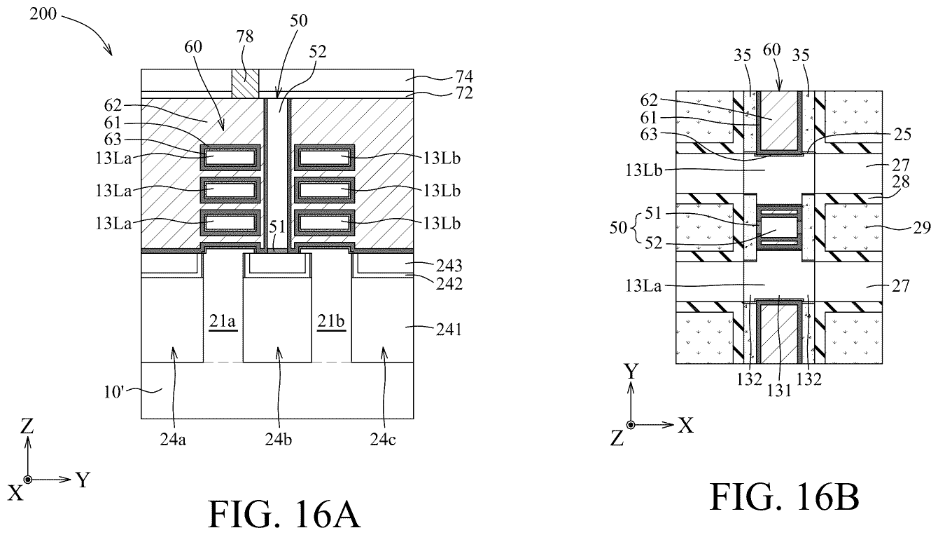

FIG. 1 is a flow diagram illustrating a method 100 for manufacturing a semiconductor structure (for example, but not limited to, a semiconductor structure 200 shown in FIGS. 15A, 15B and 15C, or a semiconductor structure 200 shown in FIGS. 16A and 16B) in accordance with some embodiments. The method 100 may include steps S01 to S10. FIGS. 2 to 16B illustrate schematic views of intermediate stages of the method 100 in accordance with some embodiments. Some repeating structures are omitted in FIGS. 2 to 16B for the sake of brevity. Additional steps can be provided before, after or during the method 100, and some steps in the method 100 may be modified, replaced, or eliminated without departure from the spirit and scope of the present disclosure.

In some embodiments, as shown in FIG. 15B, the semiconductor structure 200 is configured to be a forksheet structure, in which a dielectric wall 50 is formed on an isolation structure 24b, and each extended channel region 13La or 13Lb is in contact with a wall surface of the dielectric wall 50 and extend away from the wall surface. In some other embodiments, as shown in FIG. 16A, the semiconductor structure 200 may be configured to a gate-all-around (GAA) structure, in which four side surfaces of each extended channel region 13La or 13Lb are surrounded by a gate structure 60.

FIG. 2 is a schematic perspective view illustrating a starting substrate 10 and a lamination structure 11 formed on the starting substrate 10 in accordance with some embodiments. The structure shown in FIG. 2 is obtained after step S01 of the method 100 as shown in FIG. 1.

In some embodiments, the starting substrate 10 may include elemental semiconductor materials (such as crystalline silicon, diamond, or germanium), compound semiconductor materials (such as silicon carbide, gallium arsenide, indium arsenide, or indium phosphide), alloy semiconductor materials (such as silicon germanium, silicon germanium carbide, gallium arsenide phosphide, or gallium indium phosphide), or combinations thereof. In some embodiments, the starting substrate 10 may be a bulk semiconductor substrate, for example, but not limited to, a bulk substrate of silicon, germanium, silicon germanium, or other suitable semiconductor materials (such as the examples described earlier in the same paragraph). In some embodiments, the starting substrate 10 may be formed with an n-type well having an n-type conductivity and a p-type well having a p-type conductivity. Each of the n-type well and the p-type well may be formed by introducing an n-type impurity or a p-type impurity into the starting substrate 10 by an implantation processes. In some embodiments, the n-type impurity may include phosphorous (P, ³¹P), arsenic (As), antimony (Sb), or combinations thereof. In some embodiments, the p-type impurities may include boron or boron compound (for example, B, ¹¹B, BF₂), aluminum (Al), indium (In), gallium (Ga), or combinations thereof. In some other embodiments not shown herein, the starting substrate 10 may be configured as a semiconductor-on-insulator substrate. Other suitable materials and configurations for the starting substrate 10 are within the contemplated scope of the present disclosure.

The lamination structure 11 may include first semiconductor layers 12 and second semiconductor layers 13. The first semiconductor layers 12 are disposed to alternate with the second semiconductor layers 13 in a Z direction, which is normal to the starting substrate 10.

Each of the first semiconductor layers 12 is made of a semiconductor material that is different from a semiconductor material of the second semiconductor layers 13, so that the first semiconductor layers 12 may be selectively removed in a subsequent step, while the second semiconductor layers 13 are left substantially intact due to different etch rates. Possible semiconductor materials suitable for the first and second semiconductor layers 12, 13 are similar to those for the starting substrate 10, and thus details thereof are omitted for the sake of brevity. Other materials suitable for the first and second semiconductor layers 12, 13 are within the contemplated scope of the present disclosure. In some embodiments, the first semiconductor layers 12 are made of silicon germanium, and the second semiconductor layers 13 are made of silicon. In some embodiments, each of the first semiconductor layers 12 has a thickness ranging from about 4 nm to about 14 nm. In some embodiments, each of the second semiconductor layers 13 has a thickness ranging from about 3 nm to about 9 nm, or ranging from about 5 nm to about 8 nm.

In some embodiments, the lamination structure 11 further includes an intermediate layer 14 and a protective layer 15. The intermediate layer 14 is disposed on an uppermost one of the first semiconductor layers 12 opposite to an uppermost one of the second semiconductor layers 13. The protective layer 15 disposed on the intermediate layer 14 opposite to the uppermost one of the first semiconductor layers 12.

The protective layer 15 is made of a dielectric material. In some embodiments, the protective layer 15 is made of a nitride-based dielectric material which includes silicon nitride, silicon oxynitride, silicon carbon nitride, silicon oxycarbon nitride, other suitable nitride-based materials with low dielectric constant (low-k), or combinations thereof. In some embodiments, the protective layer 15 has a thickness ranging from about 3 nm to about 9 nm, or ranging from about 5 nm to about 8 nm.

The intermediate layer 14 includes an oxide-based material, such as silicon oxide, so as to prevent the first and second semiconductor layers 12, 13 from being affected by a stress that is induced by the protective layer 15. In some embodiments, the lamination structure 11 is formed by chemical vapor deposition (CVD), atomic layer deposition (ALD), an epitaxial growth process, or other suitable deposition techniques. In some embodiments, the epitaxial growth process may be performed by metalorganic chemical vapor deposition (MOCVD), metalorganic vapor phase epitaxy (MOVPE), plasma-enhanced chemical vapor deposition (PECVD), remote plasma-enhanced chemical vapor deposition (RP-CVD), molecular beam epitaxy (MBE), hydride vapor phase epitaxy (HVPE), liquid phase epitaxy (LPE), chloride vapor phase epitaxy (Cl-VPE), or any other suitable epitaxial growth processes. In the following description, an epitaxial growth process, unless otherwise stated or defined in this disclosure, may be performed in a way similar to the above-mentioned ones.

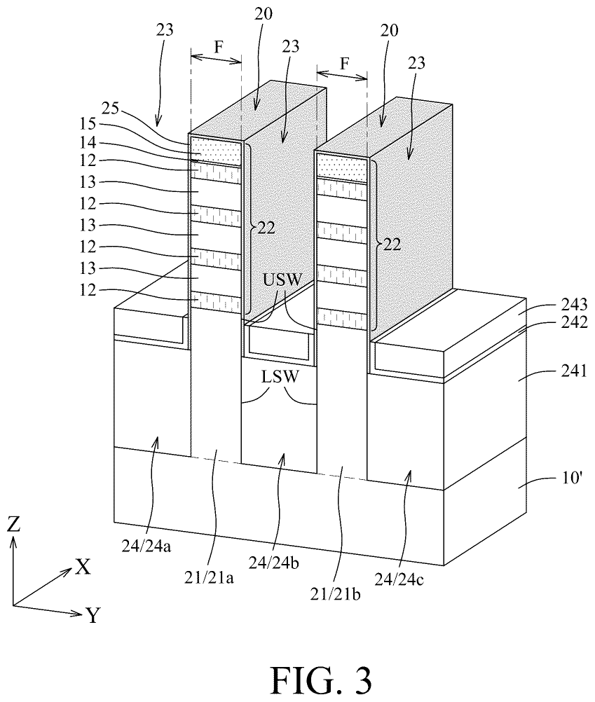

Referring to FIG. 3, the lamination structure 11 and the starting substrate 10 is patterned by a patterning process, so as to form trenches 23 extending through the lamination structure 11 and into the starting substrate 10.

In some embodiments, the patterning process includes a photolithography process and a subsequent etching process. The photolithography process may include: forming a photoresist layer over a structure to be patterned by, for example, a spin coating process; and patterning the photoresist layer by, for example, an exposure process using a photomask and a development process. The etching process, which utilizes the patterned photoresist layer as an etching mask, may include etching the structure to be patterned by, for example, dry etching, wet etching, or a combination thereof. In the following description, a patterning process, a photolithography process or an etching process, unless otherwise stated or defined in this disclosure, may be performed in a way similar to the above-mentioned ones.

As shown in FIG. 3, the lamination structure 11 is formed into upper stack regions 22 each including layers which are respectively formed from the first and second semiconductor layers 12, 13, the intermediate layer 14, and the protective layer 15, and which are still denoted by the same reference numerals. The starting substrate 10 is formed into base regions 21 (including base regions 21a, 21b) on a substrate 10′. The upper stack regions 22 are respectively disposed on the base regions 21. The base regions 21 and the upper stack stacks 22 collectively constitute fin structures 20, each of which includes one of the base regions 21 and a respective one of the upper stack regions 22 disposed thereon.

The fin structures 20 extend lengthwise along an X direction transverse to the Z direction, and two adjacent ones of the fin structures 20 are spaced apart from each other in a Y direction transverse to each of the X and Z directions. Each of the fin structures 20 has a fin width (F) measured along the Y direction. In some embodiments, the fin width (F) of the fin structure 20a may be the same as or similar to the fin width (F) of the fin structure 20b. In some other embodiments, the fin width (F) of the fin structure 20a may be different from the fin width (F) of the fin structure 20b. The number of the fin structures 20 may vary according to practical applications and is not limited to the number exemplarily shown in FIG. 3. In some embodiments, the X, Y and Z directions are perpendicular to each other.

Next, still referring to FIG. 3, trench isolations 241 are respectively formed in bottoms of the trenches 23 to expose at least the upper stack regions 22 using a suitable deposition process, followed by a planarization process and an etching process. In some embodiments, the trench isolations 241 may each be a shallow trench isolation (STI), a deep trench isolation (DTI), or other suitable structures. In some embodiments, the trench isolations 241 may include silicon oxide, silicon oxycarbide, other low-k dielectric materials, or combinations thereof. Then, a capping layer 25 is formed to protect the upper stack regions 22 and portions of the base regions 21 that are exposed from the trench isolations 241, so that the first and second semiconductor layers 12, 13 may be prevented from being damaged during subsequent processes. In some embodiments, the capping layer 25 includes or is made of silicon. In some embodiments, the capping layer 25 has a thickness ranging from about 0.3 nm to about 3 nm. Afterwards, a liner layer 242 and a hard mask layer 243 are sequentially formed to cover the capping layer 25 and the trench isolations 241, so that the hard mask layer 243 fills the trenches 23. In some embodiments, the liner layer 242 includes silicon oxide, silicon oxycarbide, other low-k dielectric materials, or combinations thereof. In some embodiments, the liner layer 242 has a thickness ranging from about 1 nm to about 3 nm. In some embodiments, the hard mask layer 243 includes a nitride-based dielectric material (such as the examples of the nitride-based dielectric material for forming the protective layer 15). The hard mask layer 243 has an etch rate that is lower than an etch rate of the liner layer 242. In some embodiments, the hard mask layer 243 has a dielectric constant value (k-value) that is higher than a k-value of the liner layer 242. Afterwards, the liner layer 242 and the hard mask layer 243 are planarized to expose the capping layer 25, and then the hard mask layer 243 are etched back to form hard mask portions (still denoted by the reference numeral 243) respectively located above the isolation trenches 241. An upper surface of each of the hard mask portions 243 may be at a same level with or below an interface between one of the base regions 21 and a respective one of the first semiconductor layers 12. Subsequently, portions of the liner layer 242 that are exposed from the hard mask portions 243 are removed, so that the liner layer 242 are formed into liner portions (still denoted by the reference numeral 242) respectively beneath the hard mask portions 243 and around sidewalls of the hard mask portions 243. The trench isolations 241, the liner portions 242 and the hard mask portions 243 collectively constitute isolation structures 24 (including isolation structures 24a, 24b, 24c), each of which includes one of trench isolations 241, a respective one of the liner portions 242, and a respective one of the hard mask portions 243. Each of the isolation structures 24 is disposed between two corresponding adjacent ones of the base regions 21. In some embodiments, an upper surface of the isolation structure 24b includes a first portion adjacent to the first base region 21a, and a second portion equidistant from the first base region 21a and the second base region 21b. In some embodiments not shown herein, the first portion may be higher than the second portion.

In some embodiments, an upper part of each of the base regions 21 is exposed from two corresponding adjacent ones of the isolation structures 24. As shown in FIG. 3, the isolation structure 24b covers a lower sidewall (LSW) of each of the base regions 21a, 21b without covering an upper sidewall (USW) of each of the base regions 21a, 21b. The structure shown in FIG. 3 is obtained after step S02 of the method 100 as shown in FIG. 1.

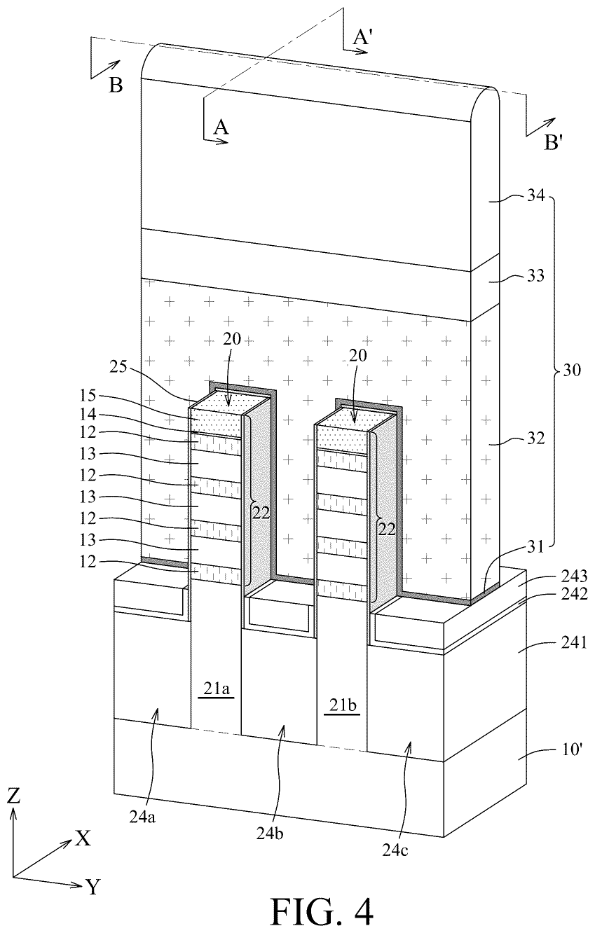

Referring to FIG. 4, a dummy structure 30 is formed. The dummy structure 30 extends lengthwise along the Y direction over the fin structures 20 and the isolation structures 24.

The dummy structure 30 includes a dummy dielectric 31, a dummy gate 32, a polish stop layer 33, and a hard mask 34. The dummy dielectric 31 is disposed over the fin structures 20 and the isolation structures 24. The dummy gate 32, the polish stop layer 33, and the hard mask 34 are sequentially formed on the dummy dielectric 31 in such order. In some embodiments, the dummy dielectric 31 may include silicon oxide, silicon nitride, silicon oxynitride, high dielectric constant (k) materials, other suitable dielectric materials, or combinations thereof. In some embodiments, the dummy gate 32 may include polycrystalline silicon, single crystalline silicon, amorphous silicon, or combinations thereof. The polish stop layer 33 and the hard mask 34 are made of different materials. In some embodiments, possible materials suitable for the polish stop layer 33 and the hard mask 34 may include a nitride-based dielectric material (such as the examples of the nitride-based dielectric material for forming the protective layer 15). Other materials suitable for the dummy structure 30 are within the contemplated scope of the present disclosure. In some embodiments, formation of the dummy structure 30 may include: sequentially forming a first dummy layer (not shown) for forming the dummy dielectric 31 and a second dummy layer (not shown) for forming the dummy gate 32 over the fin structures 20 and the isolation structures 24 by CVD, ALD, physical vapor deposition (PVD), or other suitable deposition techniques; performing a planarization process (e.g., chemical mechanical polishing, CMP) to obtain a planar upper surface of the second dummy layer; sequentially forming a third dummy layer (not shown) for forming the polish stop layer 33 and a fourth dummy layer (not shown) for forming the hard mask 34 on the planarized second dummy layer; and performing a patterning process on the first dummy layer, the planarized second dummy layer, the third dummy layer, and the fourth dummy layer to form the dummy structure 30. In some embodiments, horizontal portions of the capping layer 25 that are exposed from the dummy structure 30 are removed during the patterning process, thereby exposing portions of the protective layer 15 of each of the fin structures 20. The structure shown in FIG. 4 is obtained after step S03 of the method 100 as shown in FIG. 1.

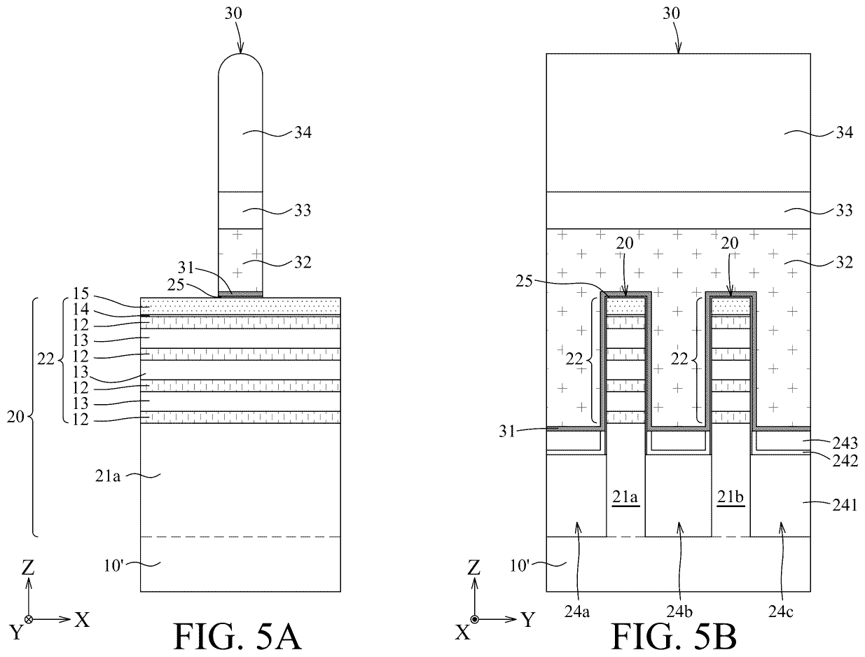

FIG. 5A is a schematic sectional view (an X-cut view) taken along line A-A′ of FIG. 4, and FIG. 5B is a schematic sectional view (a Y-cut view) taken along line B-B′ of FIG. 4.

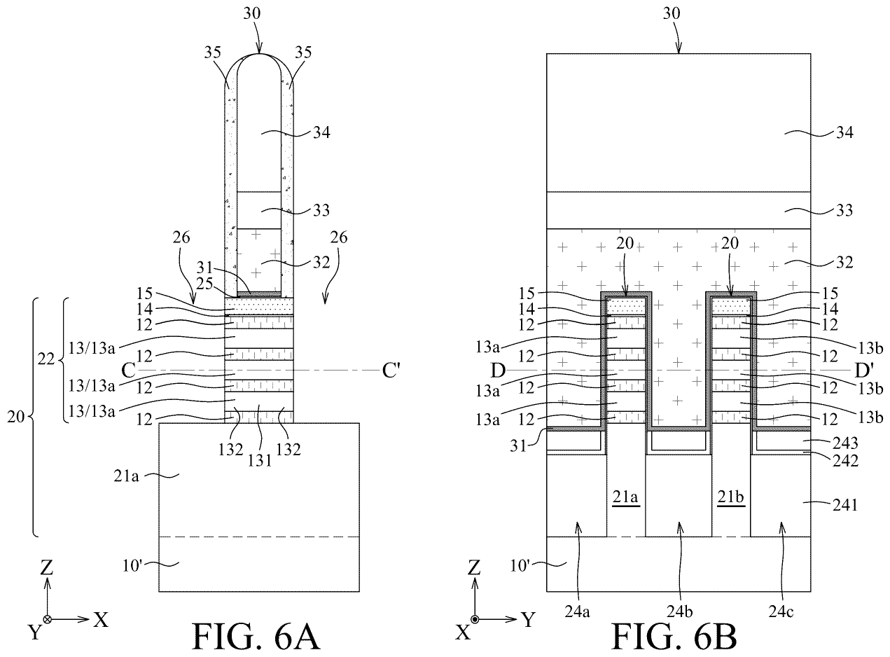

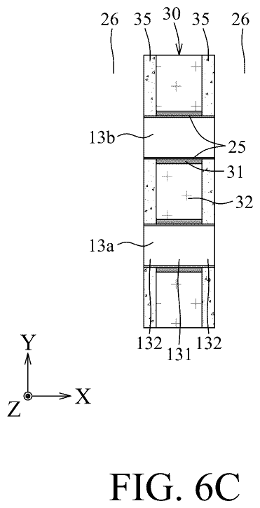

Referring to FIGS. 6A and 6B, two gate spacers 35 are formed. The two gate spacers 35 extends lengthwise along the Y direction over the fin structures 20 and the isolation structures 24, and are respectively disposed at two opposite sides of the dummy structure 30 in the X direction.

In some embodiments, formation of the two gate spacers 35 includes: forming a spacer layer (not shown) to cover the dummy structure 30, the fin structures 20 and the isolation structures 24 by CVD, ALD, PVD, or other suitable deposition techniques; and performing an anisotropic etching process on the spacer layer to remove horizontal portions of the spacer layer, while leaving vertical portions of the spacer layer. The vertical portions of the spacer layer respectively remaining at two side surfaces of the dummy structure 30 serve as the two gate spacers 35.

In some embodiments, each of the two gate spacers 35 includes or is made of, for example, but not limited to, silicon oxide, silicon nitride, carbon-doped silicon oxide (which may be referred to as silicon oxycarbide), nitride-doped silicon oxide (which may be referred to as silicon oxynitride), silicon oxycarbon nitride, silicon carbon nitride, a porous oxide material, other suitable low dielectric constant (low-k) materials, or combinations thereof. In some embodiments, each of the two gate spacers 35 may be configured as a single layer structure or a multi-layered structure.

Next, still referring to FIGS. 6A and 6B, portions of the fin structures 20 that are exposed from the gate spacers 35 and the dummy structure 30 are recessed to form source/drain recesses 26 by an etching process (for example, but not limited to, dry etching, wet etching, or a combination thereof). Accordingly, in each of the upper stack regions 22, remaining second semiconductor layers 13 serve as channels of MOSFETs, and thus are referred to as channel portions 13. In addition, the protective layer 15 is formed into a protection portion (still denoted by the reference numeral 15) which is disposed above an uppermost one of the channel portions 13.

For the sake of clarity, the channel portions located above the base region 21a are denoted by the reference numeral 13a, and the channel portions located above the base region 21b are denoted by the reference numeral 13b. In some embodiments, the channel portions 13a may be together referred to as a first channel region (still denoted by the reference numeral 13a), and the channel portions 13b may be together referred to as a second channel region (still denoted by the reference numeral 13b). The structures shown in FIGS. 6A and 6B are respectively similar to those shown in FIGS. 5A and 5B, but are obtained after step S04 of the method 100 as shown in FIG. 1.

FIG. 6C is a schematic plane view taken along line C-C′ of FIG. 6A or line D-D′ of FIG. 6A. Each of the channel regions 13a, 13b has a middle part 131 that is crossed over by the dummy structure 30, and two side parts 132 respectively crossed over by the two gate spacers 35.

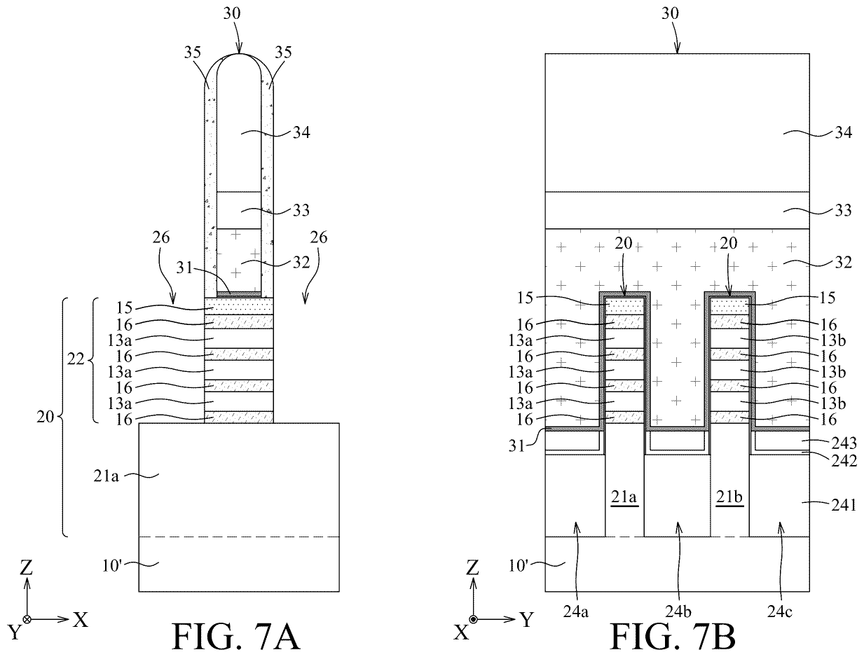

After formation of the source/drain recesses 26, the first semiconductor layers 12 and the intermediate layer 14 in each of the upper stack regions 22 are replaced with dielectric interposers 16 by suitable etching and deposition techniques, thereby obtaining the structure shown in FIGS. 7A and 7B. In some embodiments, the dielectric interposers 16 may include silicon oxide, silicon oxynitride, silicon oxycarbide, silicon oxycarbon nitride, or other suitable removable dielectric materials. Since the dielectric interposers 16 may be removed in step S10, the dielectric interposers 16 may be also referred to as sacrificial portions. The structures shown in FIGS. 7A and 7B are respectively similar to those shown in FIGS. 6A and 6B, but are obtained after step S05 of the method 100 as shown in FIG. 1. In some embodiments, replacement of the first semiconductor layers 12 and the intermediate layer 14 with the dielectric interposers 16 may be omitted. In such casse, the first semiconductor layers 12 and the intermediate layer 14 may be removed in step S10, and thus may be also referred to as sacrificial portions.

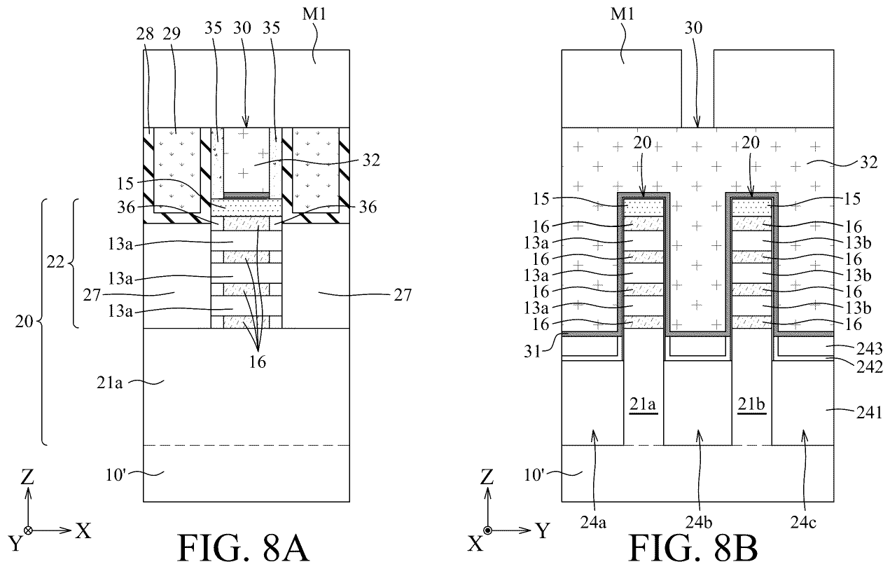

Referring to FIGS. 8A and 8B, each of the dielectric interposers 16 are trimmed by a selective etching process to have a reduced width (measured along the X direction), while the channel regions 13a, 13b are left substantially intact due to different etch rates. Then, pairs of inner spacers 36 are formed by suitable deposition and etching techniques. The inner spacers 36 in each pair are respectively formed at two opposite sides of a respective one of the dielectric interposers 16 in the X direction. In some embodiments, the inner spacers 36 may include silicon oxide, silicon oxycarbide, silicon oxynitride, silicon oxycarbide, silicon oxycarbonitride, air gap, other suitable low-k dielectric materials, or combinations thereof.

In some embodiments not shown herein, after forming the inner spacers 36, the channel regions 13a, 13b may be trimmed by a selective etching process to have a reduced width (measured along the X direction).

Next, sill referring to FIGS. 8A and 8B, source/drain portions 27 are respectively formed in the source/drain recesses 26 (see FIGS. 7A and 7B), such that each of the channel regions 13a, 13b extends between two corresponding adjacent ones of the source/drain portions 27.

In some embodiments, each of the source/drain portions 27 may include single crystalline silicon, single crystalline silicon germanium alloy, single crystalline silicon carbon alloy, single crystalline silicon carbon germanium alloy, polycrystalline silicon, polycrystalline silicon germanium, polycrystalline silicon carbon alloy, polycrystalline silicon carbon germanium alloy, or other suitable materials. The source/drain portions 27 may each be doped with an n-type dopant so as to function as a source or a drain of an n-MOSFET, or may be doped with a p-type dopant so as to function as a source or a drain of a p-MOSFET. The n-type dopant may be, for example, but not limited to, phosphorous (P, ³¹P), arsenic (As), antimony (Sb), other suitable materials, or combinations thereof. The p-type dopant may be, for example, but not limited to, boron or a boron compound (for example, B, ¹¹B, BF₂), aluminum (Al), gallium (Ga), indium (In), other suitable p-type dopants, or combinations thereof. In some other embodiments, the source/drain portions 27 serving as sources or drains of n-MOSFETs may include or be made of silicon phosphide (SiP), silicon arsenide (SiAs), or a combination thereof, and the source/drain portions 27 serving as sources or drains of p-MOSFETs may include or be made of silicon boron (SiB). In some embodiments, each of the source/drain portions 27 may be configured as a multi-layer structure including sub-layers which have different concentrations of dopants. In some embodiments, the source/drain portions 27 are formed by an epitaxial growth process.

Then, a contact etch stop layer (CESL) 28 and an inter-layer dielectric (ILD) layer 29 are sequentially formed on the source/drain portions 27 by CVD, PVD, ALD, or other possible deposition processes, followed by a planarization process (e.g., CMP) to expose the dummy gate 32 of the dummy structure 30.

In some embodiments, the CESL 28 includes or is made of a dielectric material that is different from a dielectric material of the ILD layer 29, so that the CESL 28 may serve as an etch stop point during formation of metal contacts (e.g., metal contacts 76 shown in FIG. 15A). In certain embodiments, possible dielectric materials suitable for the CESL 28 include silicon nitride, silicon oxynitride, silicon carbonnitride, other suitable dielectric materials, or combinations thereof. In some embodiments, the ILD layer 29 includes or is made of silicon oxide, doped silicon oxide (e.g., phospho-silicate glass (PSG), boro-phospho-silicate glass (BPSG), fluoro-silicate glass (FSG), carbon-doped silicon oxide (SiCOH)), other suitable low-k dielectric materials, or combinations thereof.

Afterwards, a patterned photoresist layer M1, which has a predetermined pattern, is formed by a photolithography process, so as to expose at least a portion of the dummy gate 32. In some embodiments, the predetermined pattern is elongated along the X direction, so that portions of the gate spacers 35, the CESL 28 and the ILD layer 29 may be exposed from the patterned photoresist layer M1. It is noted that a projection of the predetermined pattern on the substrate 10′ is not overlapped with a projection of each of the base regions 21a, 21b on the substrate 10'. The structures shown in FIGS. 8A and 8B are respectively similar to those shown in FIGS. 7A and 7B, but are obtained after step S06 of the method 100 as shown in FIG. 1.

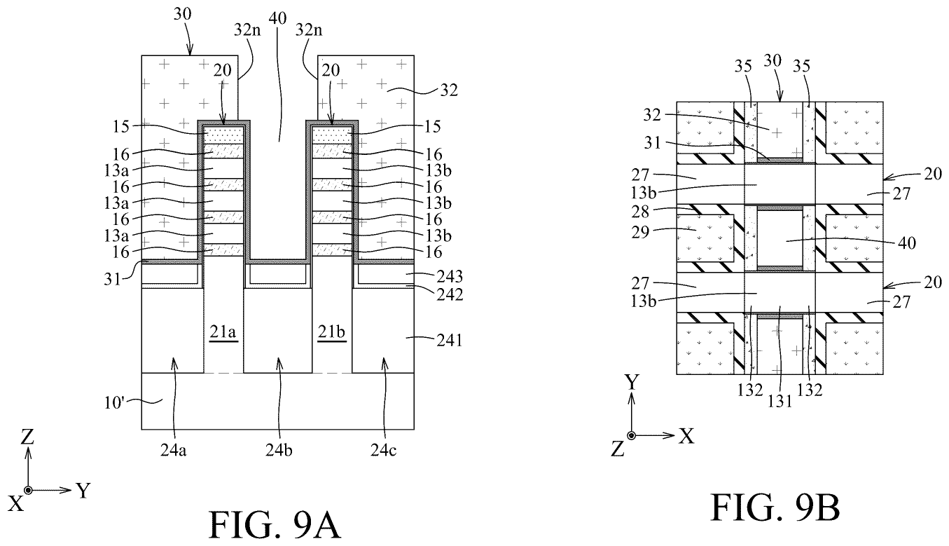

Referring to FIGS. 9A and 9B, the dummy gate 32 is patterned by an etching process, which utilizes the patterned photoresist layer M1 (see FIG. 8B) as an etching mask, so as to form a cavity 40, while the dummy dielectric 31, the gate spacers 35, the CESL 28, and the ILD layer 29 (if exposed) are left substantially intact due to different etch rates. Next, the space of the cavity 40 is enlarged by another etching process, until a portion of the dummy dielectric 31 is exposed to the cavity 40. The gate spacers 35, the CESL 28 (if exposed), and the ILD layer 29 (if exposed) are substantially intact during the etching process to enlarge the cavity 40. After the cavity 40 is enlarged, the patterned photoresist layer M1 is removed by an ashing process and/or a photoresist stripping process.

FIG. 9B is a schematic plane view similar to that of FIG. 6C, but illustrating an intermediate structure formed during step S07 of the method 100 as shown in FIG. 1. As shown in FIG. 9B, the cavity 40 is located between the two gate spacers 35 and between the two fin structures 20. In some embodiments, as shown in FIG. 9A, two inner sidewalls 32n of the patterned dummy gate 32 which define an upper opening of the cavity 40 are located on top of the fin structures 20.

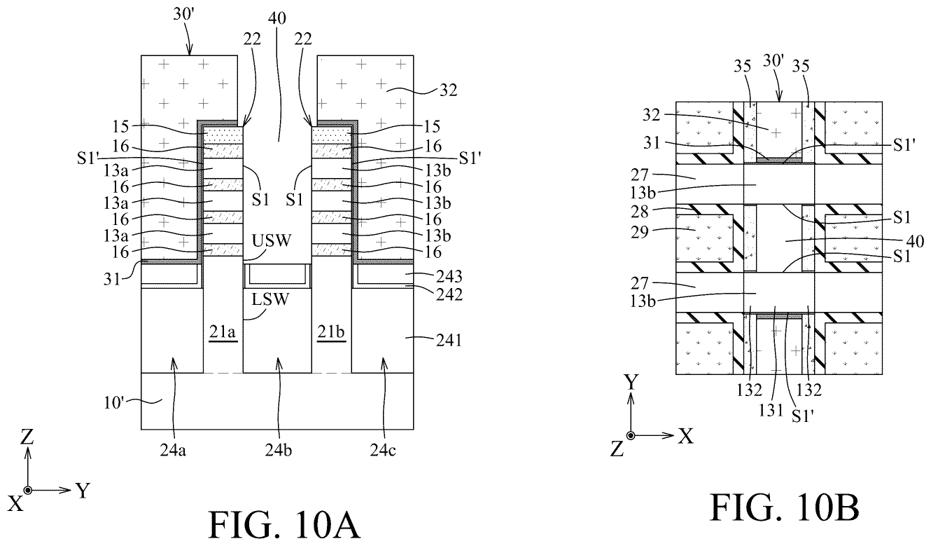

Referring to FIGS. 10A and 10B, the exposed portion of the dummy dielectric 31 that is exposed to the cavity 40 is removed by an etching process, thereby exposing portions of capping layer 25 and the isolation structure 24b, while the patterned dummy gate 32 is left substantially intact due to different etch rates. In some embodiments, the exposed portions of the capping layer 25 may be consumed or removed along with the removal of the dummy dielectric 31, so as to expose the upper stack regions 22 and the upper part of each of the base regions 21a, 21b.

As shown in FIG. 10B, the middle part 131 of each of the channel regions 13a, 13b has a side surface S1 that is exposed to the cavity 40. The side surface S1 of the middle part 131 of the channel region 13a faces the side surface S1 of the middle part 131 of the channel region 13b. In addition, as shown in FIG. 10A, the upper sidewall (USW) of each of the base regions 21a, 21b is exposed to the cavity 40, while the lower sidewall (LSW) of each of the base regions 21a, 21b is protected by the isolation structure 24b.

Still referring to FIG. 10A, the middle part 131 of each of the channel regions 13a, 13b has a side surface S1′ that is opposite to the side surface S1 in the Y direction. The side surface S1′ of the middle part 131 of the channel region 13a and the side surface S1′ of the middle part 131 of the channel region 13b face away from each other, and are protected by a remaining dummy structure 30′. The remaining dummy structure 30′ includes two dummy portions which are separated from each other by the cavity 40 in the Y direction.

It is noted that, due to the presence of the protection portion 15 in each of the upper stack regions 22, an uppermost one of the dielectric interposers 16 that is immediately beneath the protection portion 15 may be prevented from being damaged during the removal of the dummy dielectric 31, thereby preventing an upper surface of the channel region 13a (or 13b) from being exposed to the cavity 40. In some embodiments, since the gate spacers 35 are subjected to multiple etching processes during formation of the cavity 40, a sidewall surface of each of the gate spacers 35 that is exposed to the cavity 40 may have a non-linear profile (e.g., a concaved profile), thus affecting the profile of a gate isolation feature to be formed in the cavity 40 in subsequent processes (step S09). The structures shown in FIGS. 10A and 10B are respectively similar to those shown in FIGS. 9A and 9B, but are obtained after step S07 of the method 100 as shown in FIG. 1.

Next, the middle part 131 of the channel region 13a is widened in a direction toward the channel region 13b, the middle part 131 of the channel region 13b is widened in a direction toward the channel region 13a, and the two side parts 132 of each of the channel regions 13a, 13b are substantially not changed.

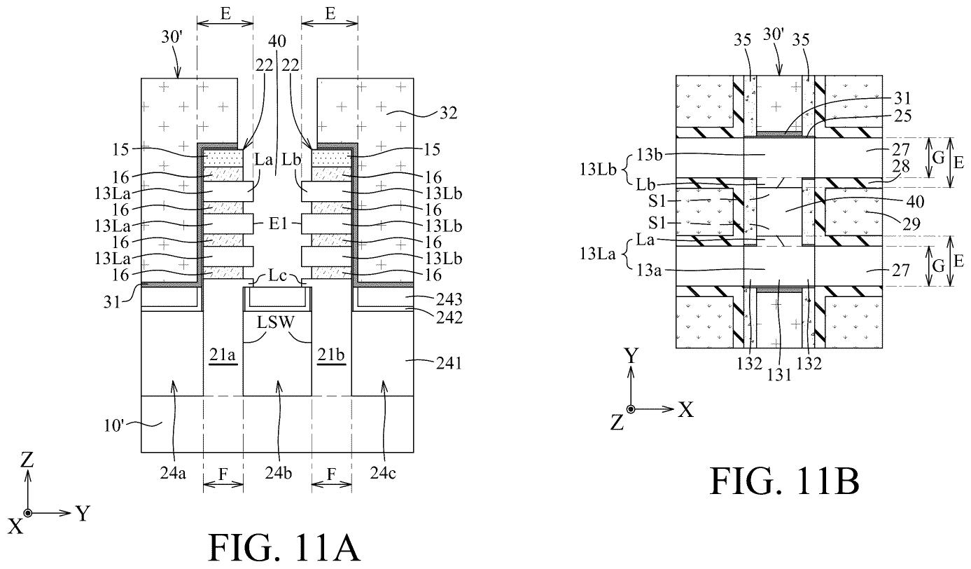

Referring to FIGS. 10A, 10B, 11A and 11B, a semiconductor material that is the same as or similar to the semiconductor material of the channel regions 13a, 13b is selectively deposited on the side surface S1 of the middle part 131 of the channel region 13a to form an extension region La, and is also selectively deposited on the side surface S1 of the middle part 131 of the channel region 13b to form an extension region Lb. In addition, the semiconductor material is selectively deposited on the upper sidewall (USW) of each of the base regions 21a, 21b to form an extension region Lc.

In some embodiments, the extension regions La, Lb, Lc may be formed by a deposition process such as an epitaxial growth process. It is noted that the semiconductor material for forming the extension regions La, Lb, Lc is less likely to be epitaxially grown on a dielectric surface (e.g., surfaces of the isolation structure 24b, the dummy dielectric 31, the protection portion 15 and the dielectric interposers 16 in each of the upper stack regions 22). In some embodiments, growth of the semiconductor material from different regions may have different growth rates. For example, a growth rate of the semiconductor material at a region abutting the dielectric surface may be lower than a growth rate of the semiconductor material at a region distal from the dielectric surface. As such, a surface of each of the extension regions La, Lb, Lc that is exposed to the cavity 40 have a non-linear profile (e.g., a convex profile). Furthermore, since the upper surface of each of the channel regions 13a, 13b is not exposed to the cavity 40, the semiconductor material for forming the extension regions La, Lb, Lc is prevented from being epitaxially grown on the upper surface of each of the channel regions 13a, 13b.

In some embodiments, prior to formation of the extension regions La, Lb, Lc, a trimming process is performed on the side surface S1 of each of the channel regions 13a, 13b and the upper sidewall (USW) of each of the base regions 21a, 21b to remove portions of the channel regions 13a, 13b and the base regions 21a, 21b, thereby obtaining a clean surface that is beneficial to the epitaxial growth of the semiconductor material. In some embodiments, prior to formation of the extension regions La, Lb, Lc, each of the channel regions 13a, 13b may be recessed from the side surface S1 by a depth ranging from about 1 Å to about 5 Å, and each of the base regions 21a, 21b may be recessed from the upper sidewall (USW) by a depth ranging from about 1 Å to about 5 Å.

Referring to FIG. 11B, the channel region 13a formed with the extension region La is referred to as an extended channel regions 13La. The channel region 13b formed with the extension region Lb is referred to as an extended channel regions 13Lb. Referring to FIG. 11A, the extension region La of the extended channel region 13La and the extension region Lb of the extended channel region 13Lb overhang the isolation structure 24b. The extension region Lc formed on the upper sidewall (USW) of each of the base regions 21a, 21b is disposed on the upper surface of the isolation structure 24b. Each of the extended channel regions 13La, 13Lb has an end surface E1 that is exposed to the cavity 40. A distance between the end surface E1 of the extended channel region 13La and the end surface E1 of the extended channel region 13Lb is less than a distance between the lower sidewall (LSW) of the base region 21a and the lower sidewall (LSW) of the base region 21b.

Referring to FIG. 11B, the extension region La of the extended channel regions 13La and the extension region Lb of the extended channel regions 13Lb are both located between the gate spacers 35. For each of the extended channel regions 13La, 13Lb, a width (E, measured along the Y direction) of the middle part 131 is greater than a width (G, measured along the Y direction) of the two side parts 132, for example, by about 1 nm to about 5 nm. The width (G) of each of the two side parts 132 is substantially the same as or similar to the fin width (F, shown in FIG. 11A). The width (E) of the middle part 131 of each of the extended channel regions 13L is also referred to as a channel width.

In some embodiments, the channel width (E) of each of the extended channel regions 13La, 13Lb is greater than the fin width (F) of a corresponding lower one of the base regions 21a, 21b by about 1 nm to about 5 nm. When the difference between the channel width (E) and the fin width (F) is too small (e.g., less than about 1 nm), the current in each of the extended channel regions 13La, 13Lb may not be sufficiently increased. When the difference between the channel width (E) and the fin width (F) is too large (e.g., greater than about 5 nm), the current in each of the extended channel regions 13La, 13Lb may be saturated (that is, has been increased and reached a maximum value).

The structures shown in FIGS. 11A and 11B are respectively similar to those shown in FIGS. 10A and 10B, but are obtained after step S08 of the method 100 as shown in FIG. 1.

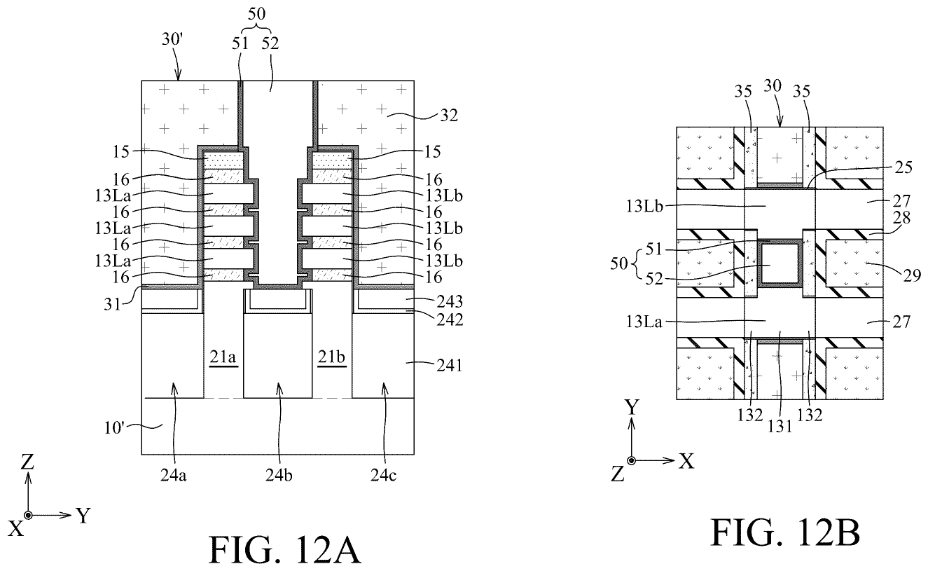

Referring to FIGS. 12A and 12B, a gate isolation feature 50 is formed in the cavity 40 by CVD, ALD, PVD, or other suitable deposition techniques, followed by a planarization process to expose the patterned dummy gate 32. In some embodiments, the gate isolation feature may also be referred to as a dielectric wall. In some embodiments, the gate isolation feature 50 has two end portions respectively interfacing the two gate spacers 35. In some embodiments, each of the two end portions may have a non-linear profile that complements the non-linear profile of each of the gate spacers 35. In some embodiments, the non-linear profile includes a convex profile.

In some embodiments, the gate isolation feature 50 includes a liner layer 51 and a filling portion 52 which is separated from each of the extended channel regions 13La, 13Lb, the two gate spacers 35 and the isolation structure 24b by the liner layer 51. In some embodiments, the liner layer 51 includes silicon oxide, silicon oxycarbide, silicon oxycarbon nitride, other low-k dielectric materials, or combinations thereof. In some embodiments, the liner layer 51 has a thickness ranging from about 0.5 nm to about 3 nm. In some embodiments, the filling portion 52 includes a nitride-based dielectric material (such as the examples of the nitride-based dielectric material for forming the protective layer 15). The filling portion 52 has an etch rate that is less than an etch rate of the liner layer 51, so that the filling portion 52 serves as an etch stop point during removal of the dielectric interposers 16 in subsequent processes (step S10). The etch rate of each of the liner layer 51 and the filling portion 52 may be adjusted by varying the proportions of silicon, oxygen, carbon, nitrogen, and/or other elements (such as hydrogen) in the dielectric material thereof. In some embodiments, the filling portion 52 has a k-value that is higher than a k-value of the liner layer 51. The structures shown in FIGS. 12A and 12B are respectively similar to those shown in FIGS. 11A and 11B, but are obtained after step S09 of the method 100 as shown in FIG. 1.

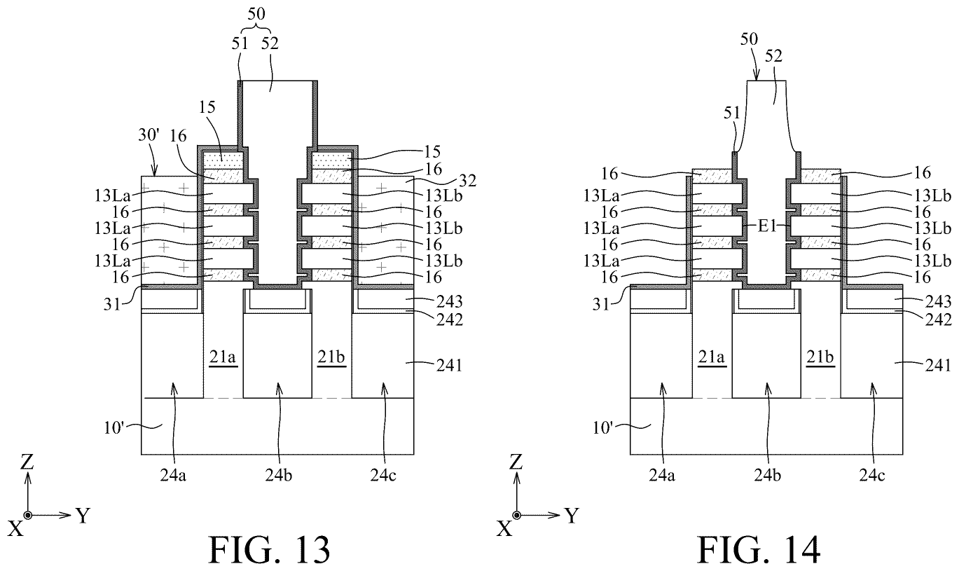

Referring to FIG. 13, the patterned dummy gate 32 is etched back by an etching process to have a reduced height measured in the Z direction, while the gate isolation feature 50, the dummy dielectric 31 and the gate spacers 35 are left substantially intact due to different etch rates. In some embodiments, an upper surface of the remaining dummy gate 32 is located at a level same as a level of the uppermost one of the dielectric interposers 16.

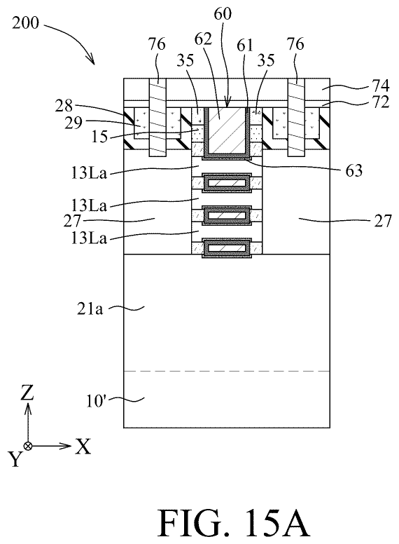

Next, portions of the dummy dielectric 31, the capping layer 25, and the liner layer 51 that are exposed from the remaining dummy gate 32 are removed by an etching process to expose a portion of the protection portion 15 that is not crossed over by the gate spacers 35. Then, the exposed portion of the protection portion 15 is removed by an etching process. In some embodiments, during the removal of the protection portion 15, an upper part of the filling portion 52 that is exposed from the liner layer 51 is trimmed to have a reduced width (measured along the Y direction). Afterwards, the remaining dummy gate 32 is removed by an etching process to expose the remaining dummy dielectric 31, thereby obtaining the structure shown in FIG. 14. Subsequently, the remaining dummy dielectric 31 and the dielectric interposers 16 are removed by an etching process to expose the extended channel regions 13La, 13Lb.

Referring to FIGS. 15A, 15B and 15C, a gate structure 60 is formed on the extended channel regions 13La, 13Lb. The gate structure 60 includes two gate portions which are separated from each other by the gate isolation feature 50. The semiconductor structure 200 is thus obtained. The structures shown in FIGS. 15A, 15B and 15C are respectively similar to those of FIGS. 8A, 14 and 12B, but are obtained after step S10 of the method 100 as shown in FIG. 1 in accordance with some embodiments.

The gate structure 60 includes a gate dielectric layer 61 disposed on the extended channel regions 13La, 13Lb, and a gate electrode 62 disposed on the gate dielectric layer 61. In some embodiments, the gate dielectric layer 61 may include or may be made of a silicon-containing dielectric material (such as silicon oxide), a metal-containing high-k dielectric material (such as metal oxides of hafnium, tantalum, titanium, zirconium, aluminum, lanthanum, yttrium, other suitable metals, or combinations thereof), other suitable dielectric materials, or combinations thereof. The gate electrode 62 may include at least one metal layer. In some embodiments, the gate electrode 62 includes at least one work function layer which is provided for adjusting threshold voltage of n-MOSFETs or p-MOSFETs in the semiconductor structure 200. Examples of the n-type work function metal include Al, titanium aluminium carbide (TiAlC), TiAl, or other suitable materials. Examples of p-type work function metal include TiN, tungsten nitride (WN), tungsten carbon nitride (WCN), molybdenum nitride (MoN), or other suitable materials. In some embodiments, the gate structure 60 may be formed by multiple deposition processes (such as CVD, ALD, PVD, or other suitable deposition processes), multiple photolithography processes, multiple etching processes, multiple thermal processes, and multiple planarization processes (e.g., CMP), or other suitable processes, so that the gate structure 60 may include different materials for adjusting threshold voltage.

In some embodiments, prior to formation of the gate dielectric layer 61, an interfacial layer 63 is further formed by an oxidation reaction that happens on a surface region of each of the extended channel portions 13La, 13Lb and a surface region of each of the base regions 21a, 21b that is exposed from the isolation structures 24a, 24c. In some embodiments, the interfacial layer 63 are made of silicon oxide. The interfacial layer 63 serves to provide good adhesion between the gate dielectric layer 61 and each of the extended channel portions 13La, 13Lb.

Referring to FIG. 15A, two remaining portions of the protection portion 15 are respectively located beneath the two gate spacers 35.

Referring to FIG. 15B, the end surface E1 of each of the extended channel regions 13La, 13Lb has a first distance to an imaginary plane (P) which is normal to the substrate 10′ and which is equidistant from the end surface E1 of the extended channel region 13La and the end surface E1 of the extended channel region 13Lb. The lower sidewall (LSW) of each of the base regions 21a, 21b has a second distance to the imaginary plane (P). The first distance is less than the second distance. In some embodiments, when the capping layer 25 and the base regions 21a, 21b are made of the same material, a remaining portion of the capping layer 25 (see FIG. 15B) on the base region 21a may be regarded as a portion of the base region 21a, and a remaining portion of the capping layer 25 (see FIG. 15B) on the base region 21b may be regarded as a portion of the base region 21b. In such case, the isolation structure 24b interfaces the lower sidewall (LSW) of each of the base regions 21a, 21b.

Referring to FIG. 15C, each of the extended channel regions 13La, 13Lb may have a recessed surface which is formed opposite to the gate isolation feature 50, and which formation is due to the removal of the remaining dummy dielectric 31 and the dielectric interposers 16.

In some embodiments, during the removal of the remaining dummy dielectric 31 and the dielectric interposers 16, the gate isolation feature 50 (see FIG. 14) may be etched back such that a first region of the end surface E1 of each of the extended channel region 13La, 13Lb is spaced apart from the remaining gate isolation feature 50 (see FIGS. 15B and 15C), while a second region of the end surface E1 is in contact with the remaining gate isolation feature 50. In such case, as shown in FIG. 15B, the gate structure 60 may cover the first region of the end surface E1 without covering the second region of the end surface E1.

In some alternative embodiments, the gate structure 60 may be configured to surround the extended channel regions 13La, 13Lb by adjusting the thickness and the material of the liner layer 51 of the gate isolation feature 50. FIGS. 16A and 16B are schematic views respectively similar to those of FIGS. 15B and 15C, but illustrating the semiconductor structure 200 having a GAA configuration in accordance with some embodiments.

To be specific, the liner layer 51 of the gate isolation feature 50 shown in FIGS. 16A and 16B has a thickness that is greater than the thickness of the liner layer 51 of the gate isolation feature 50 shown in FIGS. 15B and 15C. In addition, the difference between an etch rate of the liner layer 51 and an etch rate of the filling portion 52 shown in FIGS. 16A and 16B is greater than the difference between an etch rate of the liner layer 51 and an etch rate of the filling portion 52 shown in FIGS. 15B and 15C. For example, but not limited to, the etch rate of the filling portion 52 shown in FIGS. 16A and 16B is the same as or similar to the etch rate of the filling portion 52 shown in FIGS. 15B and 15C, and the etch rate of the liner layer 51 shown in FIGS. 16A and 16B is greater than the etch rate of the liner layer 51 shown in FIGS. 15B and 15C. In such case, during the removal of the remaining dummy dielectric 31 and the dielectric interposers 16, the gate isolation feature 50 (see FIG. 14) may be etched back until the entire end surface E1 of each of the extended channel regions 13La, 13Lb is spaced apart from the remaining gate isolation feature 50 (see FIGS. 16A and 16B). Therefore, as shown in FIG. 16A, the gate structure 60 may be formed to surround the extended channel regions 13La, 13Lb.

Referring to FIG. 16B, a portion of the liner layer 51 located between the filling portion 52 and each of the two gate spacers 35 may be etched back during the removal of the remaining dummy dielectric 31 and the dielectric interposers 16, so that the gate structure 60 further extends to be located between the filling portion 52 and each of the two gate spacers 35.

In some embodiments, the semiconductor structure 200 may be further formed with an interconnect structure thereon. In some embodiments, formation of the interconnect structure include multiple sub-steps in the following. Firstly, an etch stop layer 72 and an inter-metal dielectric (IMD) layer 74 are sequentially formed by CVD, ALD, PVD, or other suitable deposition techniques. Since possible dielectric materials suitable for the etch stop layer 72 are similar to those for forming the CESL 28, and possible dielectric materials suitable for the IMD layer 74 are similar to those for forming the ILD layer 29, details thereof are omitted for the sake of brevity. Next, metal contacts 76 (two of which are exemplarily shown in FIG. 15C) and a gate contact 78 are formed. The metal contacts 76 may be formed before or after formation of the gate contact 78. Each of the metal contacts 76 extends downwardly through the layers 74, 72, 29, 28, so as to connect to a corresponding lower one of the source/drain portions 27. In some embodiments, the metal contacts 76 may include a conductive material, such as tungsten (W), aluminum (Al), ruthenium (Ru), cobalt (Co), copper (Cu), palladium (Pd), nickel (Ni), platinum (Pt), a low resistivity metal constituent, etc., or combinations thereof. The gate contact 78 extends downwardly through the layers 74, 72 so as to connect to the gate electrode 62 of the gate structure 60. Possible conductive materials suitable for the gate contact 78 are similar to those for the metal contacts 76, and thus details thereof are omitted for the sake of brevity.

In some alternative embodiments, the semiconductor structure 200 may further include additional features, and/or some features present in the semiconductor structure 200 may be modified, replaced, or eliminated without departure from the spirit and scope of the present disclosure.

In summary, with the provision of the extended channel regions 13La, 13Lb each having an enlarged channel width along the Y direction (that is, in a direction perpendicular to the direction of a current flowing within the extended channel regions 13a, 13b), the current in each of the extended channel regions 13La, 13Lb may be increased, thereby enhancing the device performance (e.g., DC performance) of MOSFETs in the semiconductor structure 200. Furthermore, the channel regions 13a, 13b are extended immediately after the trimming process, thereby reducing defects present between the channel region 13a and the extension region La (or between the channel region 13b and the extension region Lb).

In accordance with some embodiments of the present disclosure, a semiconductor structure includes: a first fin structure and a second fin structure disposed on a substrate, the first fin structure including a first base region and a first extended channel region disposed on the first base region, the second fin structure including a second base region and a second extended channel region disposed on the second base region, the first extended channel region having a first end surface facing a second end surface of the second extended channel region; and an isolation structure disposed on the substrate and between the first base region and the second base region, an upper surface of the isolation structure including a first portion adjacent to the first base region and a second portion equidistant from the first base region and the second base region, the first portion being higher than the second portion. The first end surface has a first distance to an imaginary plane which is normal to the substrate and which is equidistant from the first end surface and the second end surface. The first sidewall has a second distance to the imaginary plane. The first distance is less than the second distance.

In accordance with some embodiments of the present disclosure, a portion of the first extended channel region and a portion of the second extended channel region are located above the isolation structure opposite to the substrate in a direction normal to the substrate.

In accordance with some embodiments of the present disclosure, a method for manufacturing a semiconductor structure includes: forming a first fin structure and a second fin structure on a substrate, the first fin structure and the second fin structure extending lengthwise along a first direction and being spaced apart from each other in a second direction transverse to the first direction, the first fin structure including a first base region and a first channel region formed on the first base region, the second fin structure including a second base region and a second channel region formed on the second base region, the first fin structure having a first fin width and the second fin structure having a second fin width along the second direction; forming an isolation structure between the first base region and the second base region; forming a dummy structure over the first fin structure, the second fin structure, and an upper surface of the isolation structure; forming a cavity in the dummy structure between the first fin structure and the second fin structure so as to separate the dummy structure into two dummy portions, and to expose a first side surface of the first channel region and a second side surface of the second channel region, the first side surface facing the second side surface; performing a deposition process on the first side surface and the second side surface to form a first extended channel region and a second extended channel region, which respectively have a first channel width and a second channel width along the second direction, the first channel width being greater than the first fin width, the second channel width being greater than the second fin width, the first extended channel region including the first channel region and a first extension region formed on the first side surface, the second extended channel region including the second channel region and a second extension region formed on the second side surface; forming a gate isolation feature in the cavity; performing an etching process to remove the two dummy portions so as to expose the first extended channel region and the second extended channel region; and forming a gate structure, the gate structure including a gate dielectric layer over the first extended channel region and the second extended channel region, and a gate electrode over the gate dielectric layer, the gate electrode including a titanium-containing material.

In accordance with some embodiments of the present disclosure, the method, after formation of the cavity and before the deposition process, further includes: performing a trimming process on the first side surface and the second side surface, so as to remove a portion of the first channel region and a portion of the second channel region.

In accordance with some embodiments of the present disclosure, the first channel region includes first channel portions vertically stacked and spaced apart from each other. The second channel region includes second channel portions vertically stacked and spaced apart from each other. The first fin structure further includes first sacrificial portions which are disposed on the first base region and which alternate with the first channel portions. The second fin structure includes second sacrificial portions which are disposed on the second base region and which alternate with the second channel portions. After the deposition process, a width of each of the first sacrificial portions along the second direction is less than the first channel width, and a width of each of the second sacrificial portions along the second direction is less than the second channel width. The first sacrificial portions and the second sacrificial portions are removed during the etching process.

In accordance with some embodiments of the present disclosure, the first fin structure further includes a first protection region disposed on an uppermost one of the first sacrificial portions opposite to an uppermost one of the first channel portions. The second fin structure further includes a second protection region disposed on an uppermost one of the second sacrificial portions opposite to an uppermost one of the second channel portions. After the deposition process, a width of the first protection region along the second direction is less than the first channel width, and a width of the second protection region along the second direction is less than the second channel width. The first protection region and the second protection region are removed during the etching process.

In accordance with some embodiments of the present disclosure, the isolation structure covers a lower sidewall of each of the first base region and the second base region. The isolation structure does not cover an upper sidewall of each of the first base region and the second base region. The deposition process is performed on the upper sidewall while the lower sidewall is protected by the isolation structure, so that a third extension region is formed on the upper sidewall of each of the first base region and the second base region.

In accordance with some embodiments of the present disclosure, the third extension region is disposed on the upper surface of the isolation structure opposite to the substrate.

In accordance with some embodiments of the present disclosure, the first extended channel region has an end surface facing an end surface of the second extended channel region. A distance between the end surface of the first extended channel region and the end surface of the second extended channel region is less than a distance between the lower sidewall of the first base region and the lower sidewall of the second base region.

In accordance with some embodiments of the present disclosure, each of the first extension region and the second extension region overhangs the isolation structure.

In accordance with some embodiments of the present disclosure, a method for manufacturing a semiconductor structure includes: forming a stack region over a substrate, the stack region extending lengthwise along a first direction, and including first semiconductor portions, second semiconductor portions disposed to alternate with the first semiconductor portions, and a protection portion disposed on an uppermost one of the first semiconductor portions opposite to an uppermost one of the second semiconductor portions; forming a dummy structure over the stack region, the dummy structure extending lengthwise along a second direction transverse to the first direction; forming two gate spacers over the stack region, the two gate spacers being respectively located at two opposite sides of the dummy structure in the first direction, each of the second semiconductor portions having a middle part crossed over by the dummy structure, and two side parts respectively crossed over by the two gate spacers; forming two source/drain recesses in the stack region, the two source/drain recesses being respectively located at two opposite sides of the dummy structure in the first direction; forming two source/drain portions respectively in the two source/drain recesses; performing a patterning process on the dummy structure to form a cavity located aside the stack and between the two gate spacers, so as to expose a side surface of the middle part of each of the second semiconductor portions, while an opposite side surface of the middle part of each of the second semiconductor portions is protected by a remaining portion of the dummy structure, the side surface and the opposite side surface facing away from each other in the second direction; performing a deposition process on the side surface of the middle part of each of the second semiconductor portions, so as to permit a width of the middle part along the second direction to be greater than a width of each of the two side parts along the second direction; and forming a gate isolation feature in the cavity, the gate isolation feature having two end portions respectively interfacing the two gate spacers, each of the two end portions having a non-linear profile.

In accordance with some embodiments of the present disclosure, a difference between the width of the middle part and the width of each of the two side parts ranges from 1 nm to 5 nm.

In accordance with some embodiments of the present disclosure, the method, after formation of the cavity and before the deposition process, further includes: performing a trimming process on the side surface so as to remove a portion of the middle part of each of the second semiconductor portions.

In accordance with some embodiments of the present disclosure, the method, after formation of the two source/drain recesses and before formation of the two source/drain portions, further includes: replacing the first semiconductor portions with dielectric interposers, respectively.

In accordance with some embodiments of the present disclosure, the method, after formation of the gate isolation feature, further includes: performing an etching process to remove the remaining portion of the dummy structure, the dielectric interposers and a portion of the protection portion, so as to expose the opposite side surface, an upper surface, and a lower surface of the middle part of each of the second semiconductor portions; and forming a gate structure on the opposite side surface, the upper surface, and the lower surface of the middle part of each of the second semiconductor portions.

In accordance with some embodiments of the present disclosure, the gate isolation feature is etched back during the etching process so as to expose a first region of the side surface of the middle part of each of the second semiconductor portions, while a second region of the first side surface is in contact with a remaining portion of the gate isolation feature. The gate structure is further formed on the first region of the first side surface of the middle part of each of the second semiconductor portions.

In accordance with some embodiments of the present disclosure, the gate isolation feature is etched back during the etching process so as to expose the side surface of the middle part of each of the second semiconductor portions, so that a remaining portion of the gate isolation feature is spaced apart from each of the second semiconductor portions. The gate structure is further formed on the side surface of the middle part of each of the second semiconductor portions.

In accordance with some embodiments of the present disclosure, the gate isolation feature includes a liner layer and a filling portion which is separated from the middle part of each of the second semiconductor portions and the two gate spacers by the liner layer. The liner layer has an etch rate that is greater than an etch rate of the filling portion.

In accordance with some embodiments of the present disclosure, a portion of the liner layer located between the filling portion and each of the two gate spacers is etched back during the etching process, so that the gate structure further extends to be located between the filling portion and each of the two gate spacers.

In accordance with some embodiments of the present disclosure, after the etching process, two remaining portions of the protection portion are respectively located beneath the two gate spacers.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a first fin structure and a second fin structure disposed on a substrate, the first fin structure including a first base region and a first extended channel region disposed on the first base region, the second fin structure including a second base region and a second extended channel region disposed on the second base region, the first extended channel region having a first end surface facing a second end surface of the second extended channel region; and
an isolation structure disposed on the substrate and between the first base region and the second base region, an upper surface of the isolation structure including a first portion adjacent to the first base region, and a second portion equidistant from the first base region and the second base region, the first portion being higher than the second portion,
the first end surface having a first distance to an imaginary plane which is normal to the substrate and which is equidistant from the first end surface and the second end surface, the first sidewall having a second distance to the imaginary plane, the first distance being less than the second distance.

2. The semiconductor structure as claimed in claim 1, wherein a portion of the first extended channel region and a portion of the second extended channel region are located above the isolation structure opposite to the substrate in a direction normal to the substrate.

3. A method for manufacturing a semiconductor structure, comprising:
forming a first fin structure and a second fin structure on a substrate, the first fin structure and the second fin structure extending lengthwise along a first direction and being spaced apart from each other in a second direction transverse to the first direction, the first fin structure including a first base region and a first channel region formed on the first base region, the second fin structure including a second base region and a second channel region formed on the second base region, the first fin structure having a first fin width and the second fin structure having a second fin width along the second direction;
forming an isolation structure between the first base region and the second base region;
forming a dummy structure over the first fin structure, the second fin structure, and an upper surface of the isolation structure;
forming a cavity in the dummy structure between the first fin structure and the second fin structure so as to separate the dummy structure into two dummy portions, and to expose a first side surface of the first channel region and a second side surface of the second channel region, the first side surface facing the second side surface;
performing a deposition process on the first side surface and the second side surface to form a first extended channel region and a second extended channel region, which respectively have a first channel width and a second channel width along the second direction, the first channel width being greater than the first fin width, the second channel width being greater than the second fin width, the first extended channel region including the first channel region and a first extension region formed on the first side surface, the second extended channel region including the second channel region and a second extension region formed on the second side surface;
forming a gate isolation feature in the cavity;
performing an etching process to remove the two dummy portions so as to expose the first extended channel region and the second extended channel region; and
forming a gate structure, the gate structure including a gate dielectric layer over the first extended channel region and the second extended channel region, and a gate electrode over the gate dielectric layer, the gate electrode including a titanium-containing material.

4. The method as claimed in claim 3, after formation of the cavity and before the deposition process, further comprising:
performing a trimming process on the first side surface and the second side surface, so as to remove a portion of the first channel region and a portion of the second channel region.

5. The method as claimed in claim 3, wherein
the first channel region includes first channel portions vertically stacked and spaced apart from each other,
the second channel region includes second channel portions vertically stacked and spaced apart from each other,
the first fin structure further includes first sacrificial portions which are disposed on the first base region and which alternate with the first channel portions,
the second fin structure includes second sacrificial portions which are disposed on the second base region and which alternate with the second channel portions,
after the deposition process, a width of each of the first sacrificial portions along the second direction is less than the first channel width, and a width of each of the second sacrificial portions along the second direction is less than the second channel width, and
the first sacrificial portions and the second sacrificial portions are removed during the etching process.

6. The method as claimed in claim 5, wherein
the first fin structure further includes a first protection region disposed on an uppermost one of the first sacrificial portions opposite to an uppermost one of the first channel portions,
the second fin structure further includes a second protection region disposed on an uppermost one of the second sacrificial portions opposite to an uppermost one of the second channel portions,
after the deposition process, a width of the first protection region along the second direction is less than the first channel width, and a width of the second protection region along the second direction is less than the second channel width, and
the first protection region and the second protection region are removed during the etching process.

7. The method as claimed in claim 3, wherein
the isolation structure covers a lower sidewall of each of the first base region and the second base region, the isolation structure not covering an upper sidewall of each of the first base region and the second base region, and
the deposition process is performed on the upper sidewall while the lower sidewall is protected by the isolation structure, so that a third extension region is formed on the upper sidewall of each of the first base region and the second base region.

8. The method as claimed in claim 7, wherein the third extension region is disposed on the upper surface of the isolation structure opposite to the substrate.

9. The method as claimed in claim 7, wherein
the first extended channel region has an end surface facing an end surface of the second extended channel region, and
a distance between the end surface of the first extended channel region and the end surface of the second extended channel region is less than a distance between the lower sidewall of the first base region and the lower sidewall of the second base region.

10. The method as claimed in claim 7, wherein each of the first extension region and the second extension region overhangs the isolation structure.

11. A method for manufacturing a semiconductor structure, comprising:
forming a stack region over a substrate, the stack region extending lengthwise along a first direction, and including first semiconductor portions, second semiconductor portions disposed to alternate with the first semiconductor portions, and a protection portion disposed on an uppermost one of the first semiconductor portions opposite to an uppermost one of the second semiconductor portions;
forming a dummy structure over the stack region, the dummy structure extending lengthwise along a second direction transverse to the first direction;
forming two gate spacers over the stack region, the two gate spacers being respectively located at two opposite sides of the dummy structure in the first direction, each of the second semiconductor portions having a middle part crossed over by the dummy structure, and two side parts respectively crossed over by the two gate spacers;
forming two source/drain recesses in the stack region, the two source/drain recesses being respectively located at two opposite sides of the dummy structure in the first direction;
forming two source/drain portions respectively in the two source/drain recesses;
performing a patterning process on the dummy structure to form a cavity located aside the stack and between the two gate spacers, so as to expose a side surface of the middle part of each of the second semiconductor portions, while an opposite side surface of the middle part of each of the second semiconductor portions is protected by a remaining portion of the dummy structure, the side surface and the opposite side surface facing away from each other in the second direction;
performing a deposition process on the side surface of the middle part of each of the second semiconductor portions, so as to permit a width of the middle part along the second direction to be greater than a width of each of the two side parts along the second direction; and
forming a gate isolation feature in the cavity, the gate isolation feature having two end portions respectively interfacing the two gate spacers, each of the two end portions having a non-linear profile.

12. The method as claimed in claim 11, wherein a difference between the width of the middle part and the width of each of the two side parts ranges from 1 nm to 5 nm.

13. The method as claimed in claim 11, after formation of the cavity and before the deposition process, further comprising:
performing a trimming process on the side surface so as to remove a portion of the middle part of each of the second semiconductor portions.

14. The method as claimed in claim 11, after formation of the two source/drain recesses and before formation of the two source/drain portions, further comprising:
replacing the first semiconductor portions with dielectric interposers, respectively.

15. The method as claimed in claim 14, after formation of the gate isolation feature, further comprising:
performing an etching process to remove the remaining portion of the dummy structure, the dielectric interposers and a portion of the protection portion, so as to expose the opposite side surface, an upper surface, and a lower surface of the middle part of each of the second semiconductor portions; and
forming a gate structure on the opposite side surface, the upper surface, and the lower surface of the middle part of each of the second semiconductor portions.

16. The method as claimed in claim 15, wherein
the gate isolation feature is etched back during the etching process so as to expose a first region of the side surface of the middle part of each of the second semiconductor portions, while a second region of the first side surface is in contact with a remaining portion of the gate isolation feature, and
the gate structure is further formed on the first region of the first side surface of the middle part of each of the second semiconductor portions.

17. The method as claimed in claim 15, wherein
the gate isolation feature is etched back during the etching process so as to expose the side surface of the middle part of each of the second semiconductor portions, so that a remaining portion of the gate isolation feature is spaced apart from each of the second semiconductor portions, and
the gate structure is further formed on the side surface of the middle part of each of the second semiconductor portions.

18. The method as claimed in claim 15, wherein the gate isolation feature includes a liner layer and a filling portion which is separated from the middle part of each of the second semiconductor portions and the two gate spacers by the liner layer, the liner layer having an etch rate that is greater than an etch rate of the filling portion.

19. The method as claimed in claim 18, wherein a portion of the liner layer located between the filling portion and each of the two gate spacers is etched back during the etching process, so that the gate structure further extends to be located between the filling portion and each of the two gate spacers.

20. The method as claimed in claim 15, wherein after the etching process, two remaining portions of the protection portion are respectively located beneath the two gate spacers.
